(19) United States
(12) Patent Application Publication
(10) Pub. No.: US 2023/0380222 A1
(43) Pub. Date: Nov. 23, 2023

(54) DISPLAY DEVICE

(71) Applicant: Japan Display Inc., Tokyo (JP)

(72) Inventor: Hiroumi KINJO, Tokyo (JP)

(73) Assignee: Japan Display Inc., Tokyo (JP)

(21) Appl. No.: 18/361,920

(22) Filed: Jul. 31, 2023

Related U.S. Application Data
(63) Continuation of application No. PCT/JP2021/044318, filed on Dec. 2, 2021.

(30) Foreign Application Priority Data
Feb. 1, 2021 (JP) 2021-014205

(51) Int. Cl. H10K 59/122

(52) U.S. Cl. CPC H10K 59/122

(57) ABSTRACT

According to one embodiment, a display device includes a substrate, an insulating layer, a first electrode layer, a rib including an opening which overlaps the first electrode, and a trench which does not overlap the first electrode, an organic layer which includes a light emitting layer and covers the first electrode and the rib, a filling member in the trench, and a second electrode covering the organic layer, the rib and the filling member. The organic layer includes a first portion covering the first electrode, a second portion covering a portion of the rib between the opening and the trench, and a third portion located in the trench and apart from the second portion.

### CROSS-REFERENCE TO RELATED APPLICATIONS

This application is a Continuation Application of PCT Application No. PCT/JP2021/044318, filed Dec. 2, 2021 and based upon and claiming the benefit of priority from Japanese Patent Application No. 2021-014205, filed Feb. 1, 2021, the entire contents of all of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a first electrode, a second electrode and an organic layer provided between these electrodes.

The organic layer may be formed in an area including a plurality of pixels. At this time, when the organic layer of an adjacent pixel (subpixel) is connected, crosstalk may occur between the pixels, and thus, the definition or color chromaticity could be reduced.

### BRIEF DESCRIPTION OF THE DRAWINGS

FIG. 1 is a diagram showing a configuration example of a display device according to a first embodiment.

FIG. 2 is a diagram showing an example of the layout of subpixels according to the first embodiment.

FIG. 3 is a schematic cross-sectional view of the display device along the line of FIG. 2.

FIG. 4 is a cross-sectional view showing an example of a layer structure which could be applied to an organic layer according to the first embodiment.

FIG. 5 is a cross-sectional view in which a rib and its vicinity are enlarged according to the first embodiment.

FIG. 6A is a cross-sectional view showing an example of a manufacturing process for obtaining the structure shown in FIG. 5.

FIG. 6B is a cross-sectional view showing a manufacturing process following FIG. 6A.

FIG. 6C is a cross-sectional view showing a manufacturing process following FIG. 6B.

FIG. 7 is a schematic cross-sectional view of a display device according to a second embodiment.

FIG. 8 is a schematic cross-sectional view of a display device according to a third embodiment.

FIG. 9 is a schematic cross-sectional view of a display device according to a fourth embodiment.

FIG. 10 is a schematic cross-sectional view of a display device according to a fifth embodiment.

FIG. 11 is a schematic cross-sectional view of a display device according to a sixth embodiment.

FIG. 12 is a schematic cross-sectional view of a display device according to a comparative example.

FIG. 13 is a schematic cross-sectional view of a display device according to a seventh embodiment.

FIG. 14 is a schematic cross-sectional view of a display device according to an eighth embodiment.

FIG. 15 is a schematic cross-sectional view of a display device according to a ninth embodiment.

FIG. 16 is a schematic cross-sectional view of a display device according to a tenth embodiment.

FIG. 17 is a schematic cross-sectional view of a display device according to an eleventh embodiment.

FIG. 18 is a plan view showing an example of subpixels, a rib and trenches according to a twelfth embodiment.

### DETAILED DESCRIPTION

In general, according to one embodiment, a display device comprises a substrate, an insulating layer provided on the substrate, a first electrode provided on the insulating layer, a rib provided on the insulating layer, and comprising an opening which overlaps the first electrode, and a trench which does not overlap the first electrode, an organic layer which includes a light emitting layer and covers the first electrode and the rib, a filling member provided in the trench, and a second electrode which covers the organic layer, the rib and the filling member. The organic layer includes a first portion which covers the first electrode, a second portion which covers, of the rib, a portion located between the opening and the trench, and a third portion located in the trench and spaced apart from the second portion.

According to another aspect of the embodiment, a display device comprises a substrate, an insulating layer provided on the substrate, a first electrode provided on the insulating layer, a rib provided on the insulating layer, and comprising an opening which overlaps the first electrode, and a trench which does not overlap the first electrode, an organic layer which includes a light emitting layer and covers the first electrode and the rib, and a second electrode which continuously covers the organic layer and an inner surface of the trench. The organic layer includes a first portion which covers the first electrode, a second portion which covers, of the rib, a portion located between the opening and the trench, and a third portion located in the trench and spaced apart from the second portion.

According to these configurations, for example, the display quality of a display device can be improved.

Embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction. A direction parallel to the Y-axis is referred to as a second direction. A direction parallel to the Z-axis is referred to as a third direction. The plane defined by the X-axis and the Y-axis is referred to as an X-Y plane. The plane defined by the X-axis and the Z-axis is referred to as an X-Z plane. When the X-Y plane is viewed, the appearance is defined as a plan view.

The display device DSP of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

### First Embodiment

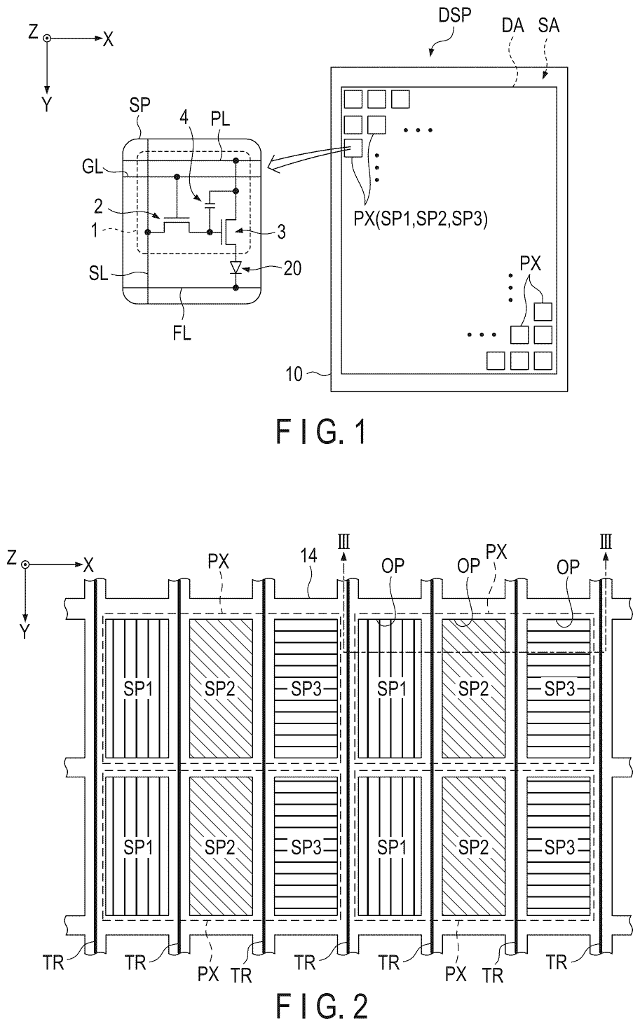

FIG. 1 is a diagram showing a configuration example of a display device DSP according to a first embodiment. The display device DSP comprises a display area DA which displays an image and a surrounding area SA outside the display area DA on an insulating substrate 10. The substrate 10 may be glass or a resinous film having flexibility.

The display area DA comprises a plurality of pixels PX arrayed in matrix in a first direction X and a second direction Y. Each pixel PX comprises a plurality of subpixels SP. For example, each pixel PX comprises a red subpixel SP1, a green subpixel SP2 and a blue subpixel SP3. It should be noted that each pixel PX may comprise four or more subpixels. Specifically, in addition to the above three subpixels, each pixel PX may comprise a subpixel which exhibits another color, or more subpixels which exhibit other colors, such as white.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

In the pixel switch 2, a gate electrode is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20. It should be noted that the configuration of the pixel circuit 1 is not limited to the example shown in the figure.

The display element 20 is an organic light emitting diode (OLED) as a light emitting element. For example, subpixel SP1 comprises a display element which emits light corresponding to a red wavelength. Subpixel SP2 comprises a display element which emits light corresponding to a green wavelength. Subpixel SP3 comprises a display element which emits light corresponding to a blue wavelength. The configuration of the display element 20 is explained later.

FIG. 2 is a diagram showing an example of the layout of subpixels SP1, SP2 and SP3. Here, this specification focuses attention on four pixels PX. In each pixel PX, subpixels SP1, SP2 and SP3 are arranged in this order in the first direction X. In other words, in the display area DA, a column consisting of a plurality of subpixels SP1 arranged in the second direction Y, a column consisting of a plurality of subpixels SP2 arranged in the second direction Y and a column consisting of a plurality of subpixels SP3 arranged in the second direction Y are alternately provided in the first direction X.

In the boundaries of subpixels SP1, SP2 and SP3, a rib 14 is provided. In the example of FIG. 2, the rib 14 has a grating shape comprising portions each located between subpixels SP which are adjacent to each other in the first direction X and portions each located between subpixels SP which are adjacent to each other in the second direction Y. The rib 14 forms an opening OP in each of subpixels SP1, SP2 and SP3.

The rib 14 comprises a plurality of trenches TR. In the example of FIG. 2, the trenches TR are located between subpixels SP1 and SP2 which are adjacent to each other in the first direction X, between subpixels SP2 and SP3 which are adjacent to each other in the first direction X and between subpixels SP1 and SP3 which are adjacent to each other in the first direction X, and all of the trenches TR extend in the second direction Y. In other words, each trench TR is located in the boundary between subpixels SP exhibiting different colors. The trenches TR may be also called grooves or slits.

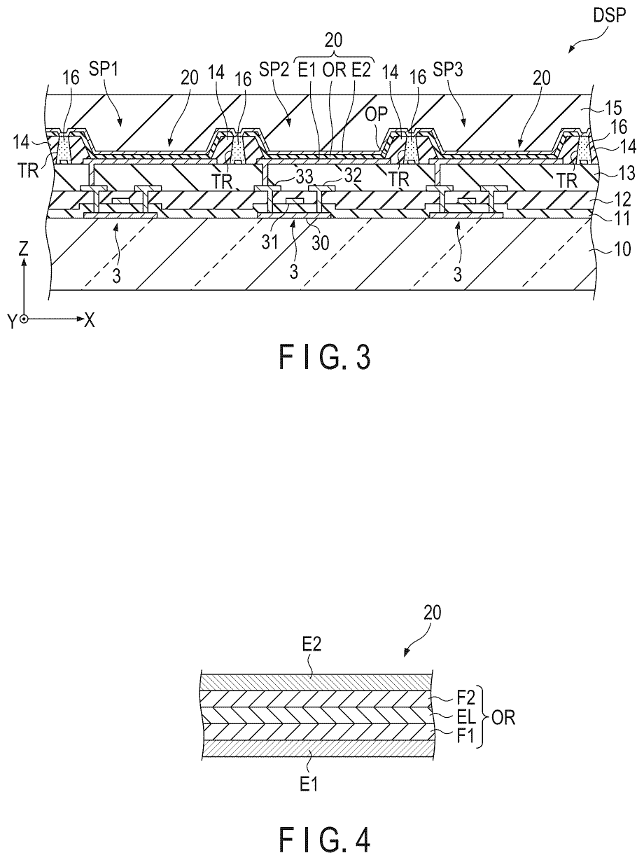

FIG. 3 is a schematic cross-sectional view of the display device DSP along the III-III line of FIG. 2. FIG. 3 shows the drive transistor 3 and the display element 20 as the elements provided in subpixels SP1, SP2 and SP3. The illustrations of the other elements are omitted in FIG. 3.

The display device DSP comprises the substrate 10 described above, insulating layers 11, 12 and 13, the rib 14 described above and a sealing layer 15. The insulating layers 11, 12 and 13 are stacked in a third direction Z on the substrate 10. For example, each of the insulating layers 11 and 12 is formed of an inorganic material, and each of the insulating layer 13, the rib 14 and the insulating layer 15 is formed of an organic material.

The drive transistor 3 comprises a semiconductor layer 30 and electrodes 31, 32 and 33. The electrode 31 corresponds to a gate electrode. One of the electrodes 32 and 33 corresponds to a source electrode, and the other one corresponds to a drain electrode. The semiconductor layer 30 is provided between the substrate 10 and the insulating layer 11. The electrode 31 is provided between the insulating layers 11 and 12. The electrodes 32 and 33 are provided between the insulating layers 12 and 13 and are in contact with the semiconductor layer 30 through contact holes penetrating the insulating layers 11 and 12.

The display element 20 comprises a first electrode E1, an organic layer OR and a second electrode E2. The first electrode E1 is an electrode provided for each subpixel SP, and may be called a pixel electrode, a lower electrode or an anode. The second electrode E2 is an electrode provided so as to be common to a plurality of subpixels SP or a plurality of display elements 20, and may be called a common electrode, an upper electrode or a cathode.

The rib 14 is provided on the insulating layer 13. The first electrode E1 is provided on the insulating layer 13 and overlaps the opening OP. The peripheral portion of the first electrode E1 is covered with the rib 14. The first electrode E1 is electrically connected to the electrode 33 through a contact hole which penetrates the insulating layer 13. The first electrode E1 is formed of a metal material. It should be noted that the first electrode E1 may be formed of a transparent conductive material such as indium tin oxide (ITO) or indium zinc oxide (IZO), or may be a stacked layer body consisting of a transparent conductive material and a metal material.

The organic layer OR covers the first electrode E1 and the rib 14. The organic layer OR is in contact with the first electrode E1 through the opening OP. The organic layer OR is partly located on the rib 14.

The second electrode E2 covers the organic layer OR. The second electrode E2 is formed of a metal material. It should be noted that the second electrode E2 may be formed of a transparent conductive material such as ITO or IZO.

FIG. 4 is a cross-sectional view showing an example of a layer structure which could be applied to the organic layer OR. For example, the organic layer OR includes a first functional layer F1, a light emitting layer EL and a second functional layer F2 stacked in order from the first electrode E1 to the second electrode E2.

When the potential of the first electrode E1 is relatively higher than that of the second electrode E2, the first electrode E1 corresponds to an anode, and the second electrode E2 corresponds to a cathode. When the potential of the second electrode E2 is relatively higher than that of the first electrode E1, the second electrode E2 corresponds to an anode, and the first electrode E1 corresponds to a cathode.

For example, when the first electrode E1 corresponds to an anode, the first functional layer F1 includes at least one of a hole injection layer, a hole transport layer and an electron blocking layer, and the second functional layer F2 includes at least one of an electron transport layer, an electron injection layer and a hole blocking layer.

The sealing layer 15 is provided on the second electrode E2. The sealing layer 15 is formed so as to be thicker than, for example, the insulating layers 11, 12 and 13 and the rib 14, protects the organic layer OR from moisture, etc., and planarizes the irregularities formed by the rib 14.

When a potential difference is formed between the first electrode E1 and the second electrode E2, the light emitting layer EL emits light. The present embodiment assumes a case where all of the light emitting layers EL included in the organic layers OR of subpixels SP1, SP2 and SP3 emit light exhibiting the same color (for example, white). In this case, for example, color filters corresponding to the colors of subpixels SP1, SP2 and SP3 may be provided above the sealing layer 15. A layer including a quantum dot which generates light exhibiting a color corresponding to each of subpixels SP1, SP2 and SP3 by the excitation caused by the light emitted from the light emitting layer EL may be provided in subpixels SP1, SP2 and SP3.

FIG. 5 is a cross-sectional view in which the rib 14 and its vicinity are enlarged. This FIG. shows the structure of the boundary between subpixels SP1 and SP2. It should be noted that a similar structure can be applied to the boundary between subpixels SP2 and SP3 and the boundary between subpixels SP1 and SP3. The elements lower than the insulating layer 13 and the sealing layer 15 are omitted.

The rib 14 comprises the trench TR which is also shown in FIG. 2. The trench TR is located between the respective first electrodes E1 of subpixels SP1 and SP2 and does not overlap these first electrodes E1. An insulating filling member 16 is provided in the trench TR. The filling member 16 is formed of, for example, the same organic material (resin) as the rib 14. It should be noted that the filling member 16 may be formed of a material which is different from that of the rib 14.

The trench TR comprises an upper portion U, a lower portion B, a first side surface SF1 and a second side surface SF2. The upper portion U corresponds to a portion which is open on the upper surface 14a of the rib 14. The lower portion B corresponds to the bottom portion of the trench TR and is open on the bottom surface of the rib 14 in the example of FIG. 5. Thus, the trench TR penetrates the rib 14. Alternatively, the trench TR may be formed so as not to penetrate the rib 14. The trench TR may penetrate the rib 14 and extend to the insulating layer 13. Further, the trench TR may penetrate the rib 14 and the insulating layer 13 and extend to a layer (for example, the insulating layer 12) which is lower than the insulating layer 13.

In the example of FIG. 5, the upper surface 16a of the filling member 16 is coincident with the upper portion U of the trench TR. In other words, the upper surface 14a of the rib 14 and the upper surface 16a of the filling member 16 form a flat surface. The upper surface 14a and the upper surface 16a do not necessarily form a flat surface. The upper surface 16a may be located so as to be slightly lower than the upper surface 14a. Alternatively, the upper surface 16a may be located so as to be slightly higher than the upper surface 14a.

The organic layer OR includes a first portion P1 which covers the first electrode E1 through the opening OP, a second portion P2 which covers, of the rib 14, the portion located between the opening OP and the trench TR, and a third portion P3 located in the trench TR. The third portion P3 is provided on the insulating layer 13 and is not in contact with the first electrode E1. Further, the third portion P3 is spaced apart from the second portion P2 and is covered with the filling member 16.

The second electrode E2 continuously covers the first portion P1, the second portion P2 and the upper surface 16a. As the trench TR is filled with the filling member 16, the second electrode E2 is not included in the trench TR. The second electrode E2 is not in contact with the third portion P3.

In the present embodiment, the trench TR has an inverse tapered shape. Here, the inverse tapered shape refers to the shape in which the second width W2 of the lower portion B is greater than the first width W1 of the upper portion U (W1<W2). The side surfaces SF1 and SF2 of the trench TR may be flat surfaces which incline with respect to the third direction Z as shown in FIG. 5, or may be curved surfaces.

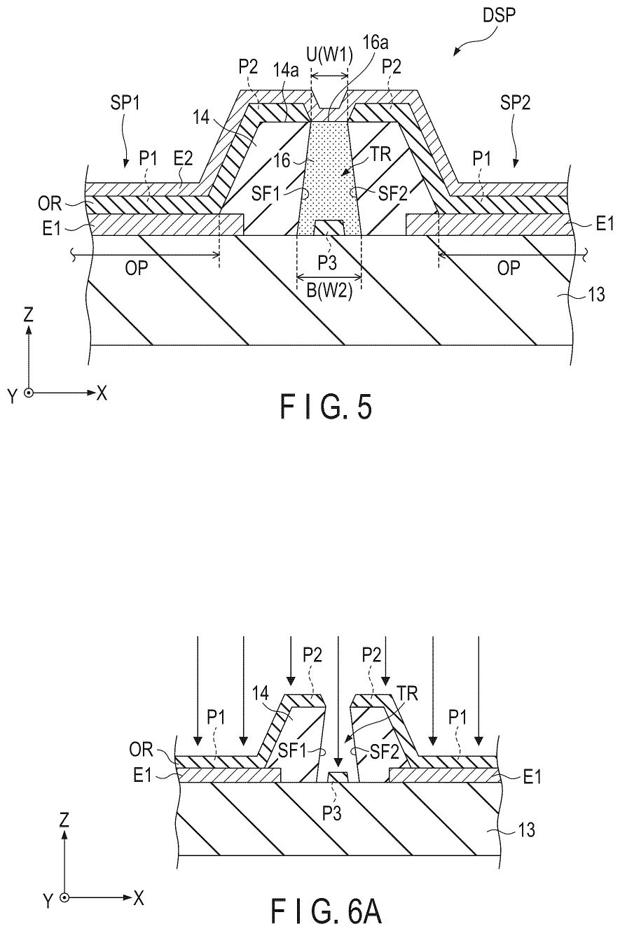

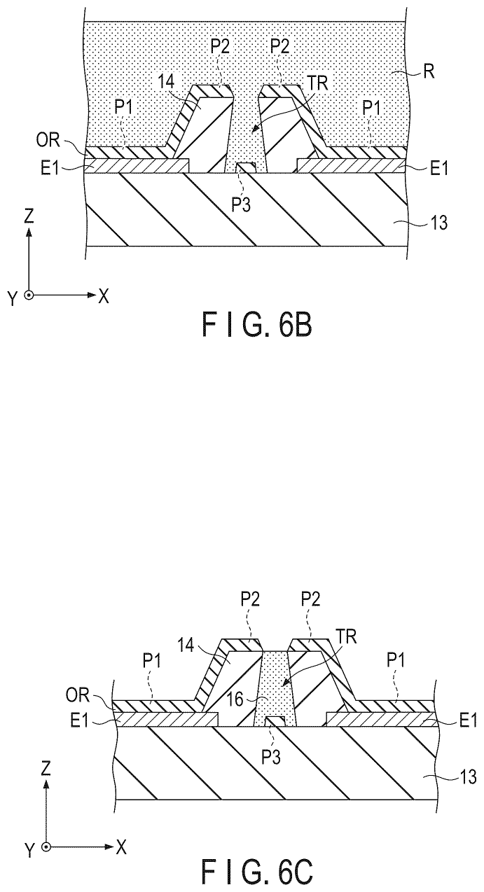

FIG. 6A is a cross-sectional view showing an example of a manufacturing process for obtaining the structure shown in FIG. 5. FIG. 6B is a cross-sectional view showing a manufacturing process following FIG. 6A. FIG. 6C is a cross-sectional view showing a manufacturing process following FIG. 6B.

FIG. 6A shows the process in which the organic layer OR is formed on the insulating layer 13, the first electrode E1 and the rib 14 by vacuum deposition. For example, the insulating layer 13, the first electrode E1 and the rib 14 are exposed to an organic material from an evaporation source in the entire display area DA. By this process, the first portion P1 is formed on the first electrode E1, and the second portion P2 is formed on the rib 14. Further, the third portion P3 is formed inside the trench TR.

In the present embodiment, the trench TR has an inverse tapered shape. Thus, the organic material from the evaporation source is not easily attached to the side surface SF1 or SF2. For this reason, the second portion P2 is spaced apart from the third portion P3. In other words, the organic layers OR of adjacent subpixels SP are separated from each other in the trench TR.

After the formation of the organic layers OR, as shown in FIG. 6B, a resin layer R which covers the organic layers OR is formed. The resin layer R is formed so as to be thicker than the rib 14 and also fills the trench TR.

Subsequently, as shown in FIG. 6C, the resin layer R located outside the trench TR is removed. By this process, the filling member 16 which fills the trench TR is formed. The resin layer R may be removed by, for example, etching using a mask. Alternatively, of the resin layer R, the portion located in the trench TR may be cured by ultraviolet light, and the other portion may be removed by etching. Alternatively, both the process of using a mask and the process of using ultraviolet light in the above manner can be employed together. Further, as an example which is different from FIG. 6B and FIG. 6C, the filling member 16 may be formed by an ink-jet method in which a resinous material is dropped to the trench TR.

After the filling member 16 is formed as shown in FIG. 6C, the second electrode E2 is formed on the organic layers OR and the filling member 16. By this process, the structure shown in FIG. 5 can be obtained.

The organic layer OR formed in the entire display area DA can be divided at the position of each trench TR by providing the trenches TR in the rib 14 provided in the boundaries of subpixels SP like the present embodiment described above. By this configuration, crosstalk is prevented between subpixels SP exhibiting different colors, and thus, the display quality of the display device DSP is improved. When the organic layer OR is divided by the trenches TR, the manufacturing process is considerably simplified compared with a case where the organic layer OR is formed for each subpixel SP by a mask. When each trench TR has an inverse tapered shape like the present embodiment, the organic layer OR can be more satisfactorily divided.

Further, in the present embodiment, the trench TR is filled with the filling member 16, and the second electrode E2 is formed on such a structure. If the filling member 16 is not provided, the second electrode E2 is not satisfactorily formed on the inner surface of the trench TR and could be divided in the trench TR. However, when the trench TR is filled with the filling member 16, a risk that the second electrode E2 is divided can be considerably reduced.

Various desirable effects can be obtained from the present embodiment in addition to the above description.

Hereinafter, this specification discloses the other embodiments of the display device DSP. The structures which are not particularly referred to in these embodiments are the same as those of the first embodiment.

### Second Embodiment

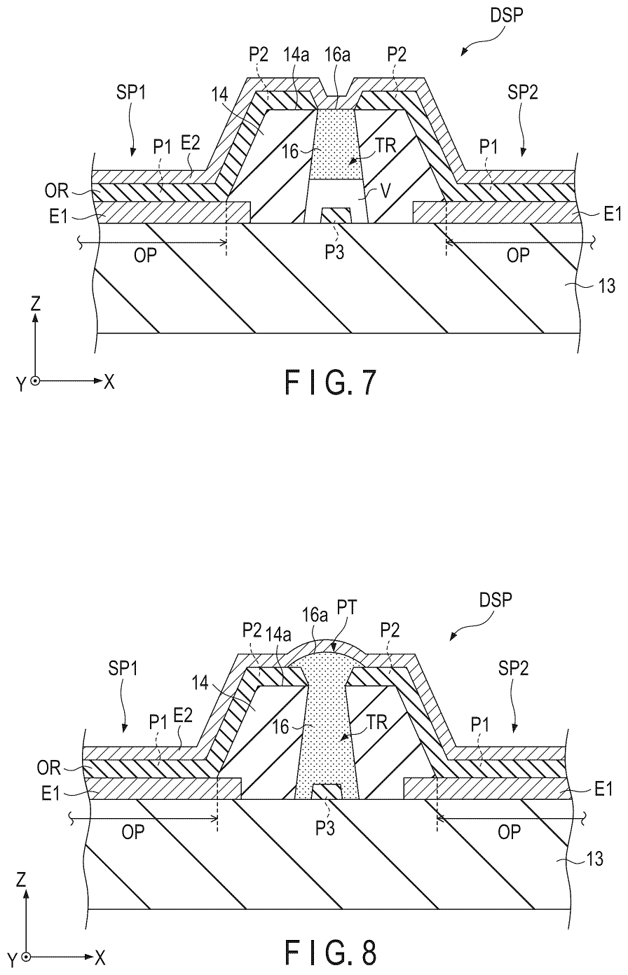

FIG. 7 is a schematic cross-sectional view of a display device DSP according to a second embodiment. This figure shows the structure of the boundary between subpixels SP1 and SP2. It should be noted that a similar structure can be applied to the boundary between subpixels SP2 and SP3 and the boundary between subpixels SP1 and SP3.

In the example of FIG. 7, a void V is formed in the lower area of a trench TR. A filling member 16 fills the upper area of the trench TR relative to the void V. A third portion P3 provided in an organic layer OR is located in the void V.

Even in a case where the trench TR comprises the void V on the lower side, when the upper side of the trench TR is filled with the filling member 16, a risk that a second electrode E2 is divided in the trench TR can be prevented in a manner similar to that of the first embodiment.

### Third Embodiment

FIG. 8 is a schematic cross-sectional view of a display device DSP according to a third embodiment. This figure shows the structure of the boundary between subpixels SP1 and SP2. It should be noted that a similar structure can be applied to the boundary between subpixels SP2 and SP3 and the boundary between subpixels SP1 and SP3.

In the example of FIG. 8, part of a filling member 16 overflows from a trench TR and forms a protrusion PT. The protrusion PT protrudes to the upper side relative to a second portion P2 provided in an organic layer OR located on a rib 14 and covers part of the second portion P2. For example, the upper surface of the protrusion PT has a curved shape which protrudes to the upper side.

In this manner, even when the filling member 16 overflows from the trench TR, a second electrode E2 is not divided by the trench TR, and effects similar to those of the first embodiment can be obtained.

### Fourth Embodiment

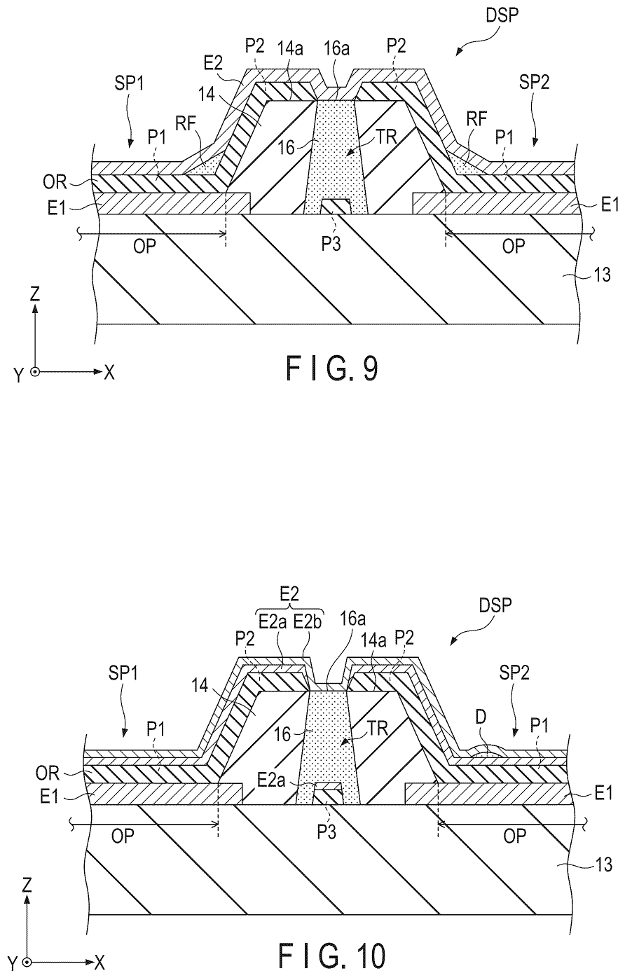

FIG. 9 is a schematic cross-sectional view of a display device DSP according to a fourth embodiment. This figure shows the structure of the boundary between subpixels SP1 and SP2. It should be noted that a similar structure can be applied to the boundary between subpixels SP2 and SP3 and the boundary between subpixels SP1 and SP3.

In the example of FIG. 9, an insulating protective member RF is provided in the edge portion of an opening OP (around the base of a rib 14). The protective member RF is located between an organic layer OR and a second electrode E2. For example, the protective member RF linearly extends in a second direction Y in a manner similar to that of the trench TR shown in FIG. 2.

A failure such as the reduction in the thickness of the organic layer OR easily occurs in a portion where the organic layer OR is deformed by the rib 14, in other words, in the boundary portion between a first portion P1 and a second portion P2. When the protective member RF is provided, such a portion is not in contact with the second electrode E2, thereby preventing current leak and display failure.

For example, the protective member RF is formed of the same material as a filling member 16. The protective member RF can be formed by leaving the resin layer R shown in FIG. 6B in the edge portion of the opening OP. In this case, as the filling member 16 is formed by the same process as the protective member RF, the manufacturing process of the display device DSP can be simplified.

### Fifth Embodiment

FIG. 10 is a schematic cross-sectional view of a display device DSP according to a fifth embodiment. This figure shows the structure of the boundary between subpixels SP1 and SP2. It should be noted that a similar structure can be applied to the boundary between subpixels SP2 and SP3 and the boundary between subpixels SP1 and SP3.

In the example of FIG. 10, a second electrode E2 includes a conductive first layer E2a and a conductive second layer E2b. The first layer E2a and the second layer E2b are formed of, for example, metal materials. At least one of the first layer E2a and the second layer E2b may be formed of a transparent conductive material. The first layer E2a and the second layer E2b may be formed by, for example, vacuum deposition. However, they may be formed by another method.

The first layer E2a covers the first and second portions P1 and P2 of an organic layer OR and is divided in a trench TR. Part of the first layer E2a is also located in the trench TR and covers the third portion P3 of the organic layer OR. The first layer E2a may be attached to at least part of the inner circumferential surface of the trench TR. Of the first layer E2a, the portion located in the trench TR is covered with a filling member 16.

The second layer E2b covers, of the first layer E2a, the portion located outside the trench TR. The second layer E2b covers the upper surface 16a of the filling member 16 above the trench TR.

In the manufacturing process of this display device DSP, the first layer E2a is formed after the formation of the organic layer OR and before the filling member 16. To the contrary, the second layer E2b is formed after the filling member 16.

When the filling member 16 is formed by the process shown in FIG. 6B and FIG. 6C, a resin layer R may partly remain in an opening OP like the residue D shown in FIG. 10. If such a residue D is generated in the configuration of each embodiment described above, the organic layer OR is not in contact with the second electrode E2 in this portion, and thus, a display failure may occur. In the configuration of the present embodiment, even if the residue D is generated, the residue D is located between the first layer E2a and the second layer E2b. Thus, the second electrode E2 (the first layer E2a) is in contact with the organic layer OR even in the portion of the residue D. In this manner, a display failure can be prevented.

In addition, as the first layer E2a is formed before the resin layer R, the organic layer OR is entirely covered with the first layer E2a. By this configuration, the contact between the organic layer OR and the resin layer R (including the filling member 16 and the residue D) is prevented. If the organic layer OR is in contact with the resin layer R, there is a possibility that the resin layer R has an undesired effect on the organic layer OR in the portion. However, the configuration of the present embodiment can prevent such a situation.

### Sixth Embodiment

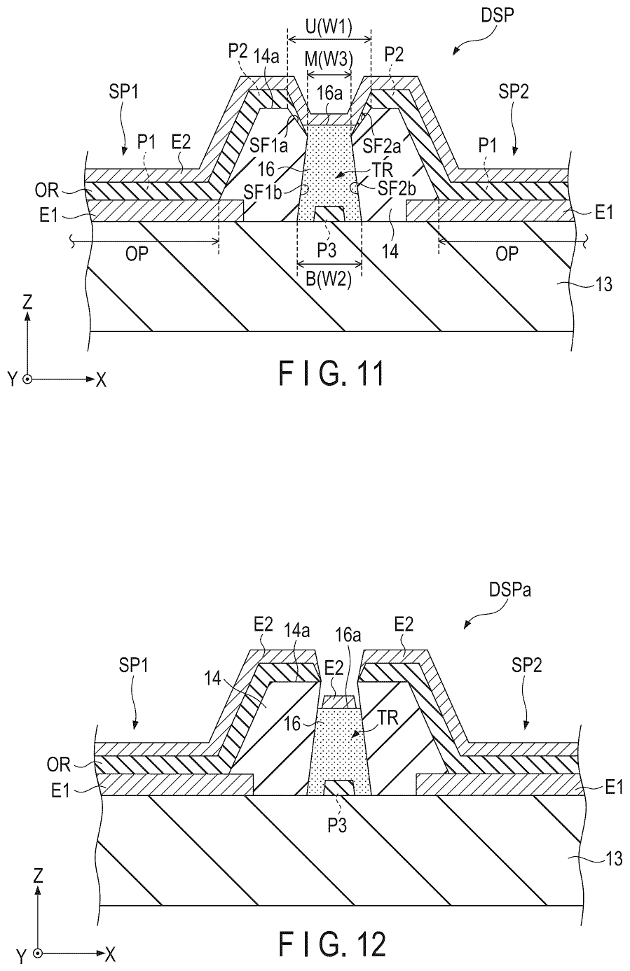

FIG. 11 is a schematic cross-sectional view of a display device DSP according to a sixth embodiment. This figure shows the structure of the boundary between subpixels SP1 and SP2. It should be noted that a similar structure can be applied to the boundary between subpixels SP2 and SP3 and the boundary between subpixels SP1 and SP3.

In the example of FIG. 11, a trench TR comprises an upper portion U, a lower portion B and a middle portion M located between the upper portion U and the lower portion B. For example, the middle portion M is the portion having the least width in the trench TR. The middle portion M is located on the upper portion U side relative to the center of the trench TR in a third direction Z. The upper portion U has a first width W1. The lower portion B has a second width W2. The middle portion M has a third width W3.

In the trench TR, the area located between the upper portion U and the middle portion M has a forward tapered shape. Here, the forward tapered shape refers to the shape in which the first width W1 of the upper portion U is greater than the third width W3 of the middle portion M (W1>W3). The first side surface SF1a and the second side surface SF2a in this area may be flat surfaces which incline with respect to the third direction Z as shown in FIG. 11 or may be curved surfaces.

In the trench TR, the area located between the middle portion M and the lower portion B has an inverse tapered shape. Here, the inverse tapered shape refers to the shape in which the second width W2 of the lower portion B is greater than the third width W3 of the middle portion M (W3<W2). The first side surface SF1b and the second side surface SF2b in this area may be flat surfaces which incline with respect to the third direction Z as shown in FIG. 11 or may be curved surfaces.

Thus, in the example of FIG. 11, the third width W3 is less than the first width W1 and the second width W2 (W3<W1, W2). In the example of FIG. 11, the first width W1 is greater than the second width W2 (W1>W2). However, the first width W1 may be less than or equal to the second width W2 (W1≤W2).

The side surfaces SF1a and SF2a are covered with an organic layer OR. The upper surface 16a of a filling member 16 is located between the middle portion M and the upper portion U. The upper surface 16a may form a flat surface with the upper surface 14a of a rib 14 in a manner similar to that of the example of FIG. 5. A second electrode E2 coves the first and second portions P1 and P2 of the organic layer OR and the upper surface 16a.

FIG. 12 is a schematic cross-sectional view of a display device DSPa according to a comparative example. In this comparative example, a trench TR has an inverse tapered shape in a manner similar to that of the example of FIG. 5. However, the trench TR is not sufficiently filled with a filling member 16. An upper surface 16a is located on the lower side relative to an upper surface 14a. In this configuration, a groove having an inverse tapered shape is formed above the filling member 16. Thus, a second electrode E2 could be divided in the trench TR.

To the contrary, in the configuration shown in FIG. 11, even in a case where the trench TR is not sufficiently filled with the filling member 16, when the upper surface 16a is located between the middle portion M and the upper portion U, a groove having an inverse tapered shape is not formed above the filling member 16. In other words, the groove above the filling member 16 has a forward tapered shape and can be formed without dividing the second electrode E2.

### Seventh Embodiment

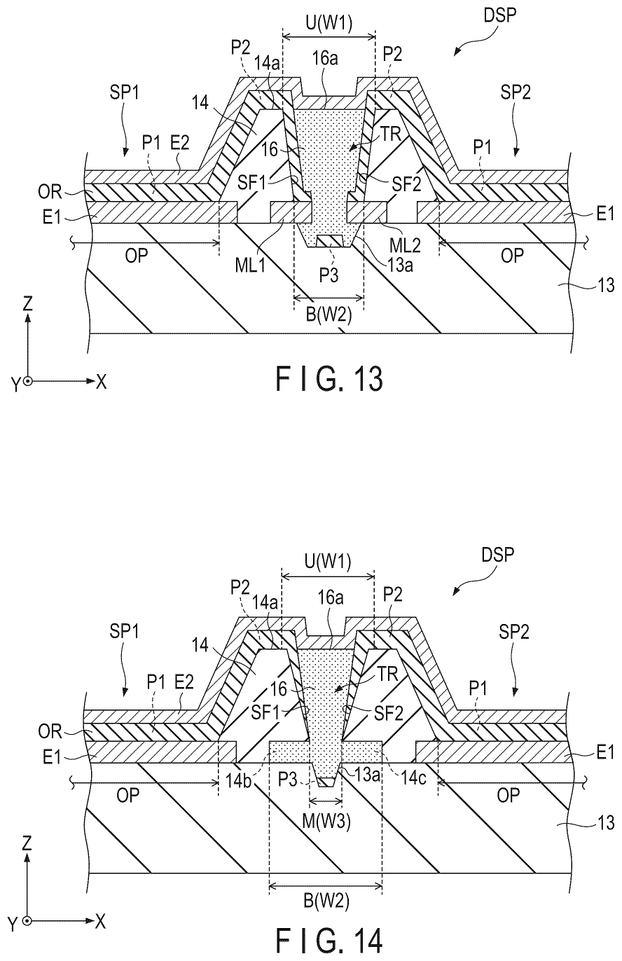

FIG. 13 is a schematic cross-sectional view of a display device DSP according to a seventh embodiment. This figure shows the structure of the boundary between subpixels SP1 and SP2. It should be noted that a similar structure can be applied to the boundary between subpixels SP2 and SP3 and the boundary between subpixels SP1 and SP3.

In the example of FIG. 13, a trench TR has a forward tapered shape. In other words, the first width W1 of an upper portion U is greater than the second width W2 of a lower portion B (W1>W2). An insulating layer 13 comprises a recess 13a under the trench TR. A first metal layer ML1 and a second metal layer ML2 are provided between the insulating layer 13 and a rib 14. The recess 13a, the first metal layer ML1 and the second metal layer ML2 linearly extend in a second direction Y in a manner similar to that of, for example, the trench TR shown in FIG. 2.

The first metal layer ML1 protrudes from a first side surface SF1 and blocks part of the recess 13a. The second metal layer ML2 protrudes from a second side surface SF2 and blocks part of the recess 13a. The metal layers ML1 and ML2 face each other across an intervening gap in the trench TR. The recess 13a is connected to the trench TR via the gap. Each of the metal layers ML1 and ML2 can be formed of the same metal material as a first electrode E1. However, each of the metal layers ML1 and ML2 may be formed of a metal material different from that of the first electrode E1. Instead of the metal layers ML1 and ML2, layers which have shapes similar to those of the metal layers ML1 and ML2 and are formed of silicon oxide (SiOx) or silicon nitride (SiNx) may be provided. The metal layers ML1 and ML2 are spaced apart from the first electrodes E1.

The second portion P2 of an organic layer OR covers the side surfaces SF1 and SF2. The second portion P2 also covers the upper surfaces of the metal layers ML1 and ML2 protruding from the side surfaces SF1 and SF2, respectively. The third portion P3 of the organic layer OR is located in the recess 13a and is spaced apart from the second portion P2.

In a manner similar to that of the example of FIG. 5, the upper surface 16a of a filling member 16 is coincident with the upper portion U of the trench TR. It should be noted that the upper surface 16a may have a shape which protrudes from the upper portion U like the protrusion PT shown in FIG. 8. The upper portion 16a may be located between the metal layers ML1 and ML2 and the upper portion U. A second electrode E2 continuously covers a first portion P1, the second portion P2 and the upper surface 16a of the filling member 16.

In the manufacturing process of this display device DSP, the rib 14 is formed on the metal layers ML1 and ML2, and the trench TR is formed by etching. By this etching, the recess 13a is formed in the insulating layer 13. When the materials of the metal layers ML1 and ML2 and the rib 14 are selected such that the etching rates of the metal layers ML1 and ML2 are less than the etching rate of the rib 14, an overhang structure in which the metal layers ML1 and ML2 protrude from the side surfaces SF1 and SF2 can be realized by the etching.

When the organic layer OR is formed by vacuum deposition after the formation of the trench TR, the organic layer OR is divided in the gap of the metal layers ML1 and ML2. Subsequently, the filling member 16 is formed by, for example, the method shown in FIG. 6B and FIG. 6C, and the second electrode E2 is formed on the organic layer OR and the filling member 16. As the trench TR is filled with the filling member 16, the division of the second electrode E2 can be prevented in a manner similar to that of each embodiment described above.

### Eighth Embodiment

FIG. 14 is a schematic cross-sectional view of a display device DSP according to an eighth embodiment. This figure shows the structure of the boundary between subpixels SP1 and SP2. It should be noted that a similar structure can be applied to the boundary between subpixels SP2 and SP3 and the boundary between subpixels SP1 and SP3.

In the example of FIG. 14, the first side surface SF1 of a trench TR comprises a first recess 14b which is depressed toward the first electrode E1 of subpixel SP1, and the second side surface SF2 comprises a second recess 14c which is depressed toward the first electrode E1 of subpixel SP2. An insulating layer 13 comprises a recess 13a which is connected to the trench TR. The recesses 14b and 14c correspond to the areas surrounded by the inner surface of the trench TR and the insulating layer 13. The recesses 13a, 14b and 14c linearly extend in a second direction Y in a manner similar to that of, for example, the trench TR shown in FIG. 2.

From another viewpoint, the trench TR comprises an upper portion U, a lower portion B and a middle portion M between the upper portion U and the lower portion B in a manner similar to that of the example of FIG. 11. The third width W3 of the middle portion M is less than the first width W1 of the upper portion U and the second width W2 of the lower portion B (W3<W1, W2). In the example of FIG. 14, the second width W2 is greater than the first width W1 (W1<W2). The middle portion M is located on the lower portion B side relative to the center of the trench TR in a third direction Z.

The second portion P2 of an organic layer OR covers at least part of the side surfaces SF1 and SF2. The third portion P3 of the organic layer OR is located in the recess 13a and is spaced apart from the second portion P2. The width of the recess 13a is less than the second width W2.

In a manner similar to that of the example of FIG. 5, the upper surface 16a of a filling member 16 is coincident with the upper portion U of the trench TR. It should be noted that the upper surface 16a may have a shape which protrudes from the upper portion U like the protrusion PT shown in FIG. 8. The upper surface 16a may be located between the middle portion M and the upper portion U. The filling member 16 fills the recesses 13a, 14b and 14c. A second electrode E2 continuously covers a first portion P1, the second portion P2 and the upper surface 16a of the filling member 16.

To manufacture this display device DSP, for example, the metal layers ML1 and ML2 shown in FIG. 13 are formed on the insulating layer 13. A rib 14 is formed on this structure. The trench TR is formed by etching. By this etching, the recess 13a is formed in the insulating layer 13. When the materials of the metal layers ML1 and ML2 and the rib 14 are selected such that the etching rates of the metal layers ML1 and ML2 are greater than the etching rate of the rib 14, the metal layers ML1 and ML2 are removed by the etching, and the recesses 14b and 14c having the shapes shown in FIG. 14 are formed.

When the organic layer OR is formed by vacuum deposition after the formation of the trench TR, the organic layer OR is divided in the middle portion M. Subsequently, the filling member 16 is formed by, for example, the method shown in FIG. 6B and FIG. 6C, and the second electrode E2 is formed on the organic layer OR and the filling member 16. As the trench TR is filled with the filling member 16, the division of the second electrode E2 can be prevented in a manner similar to that of each embodiment described above.

### Ninth Embodiment

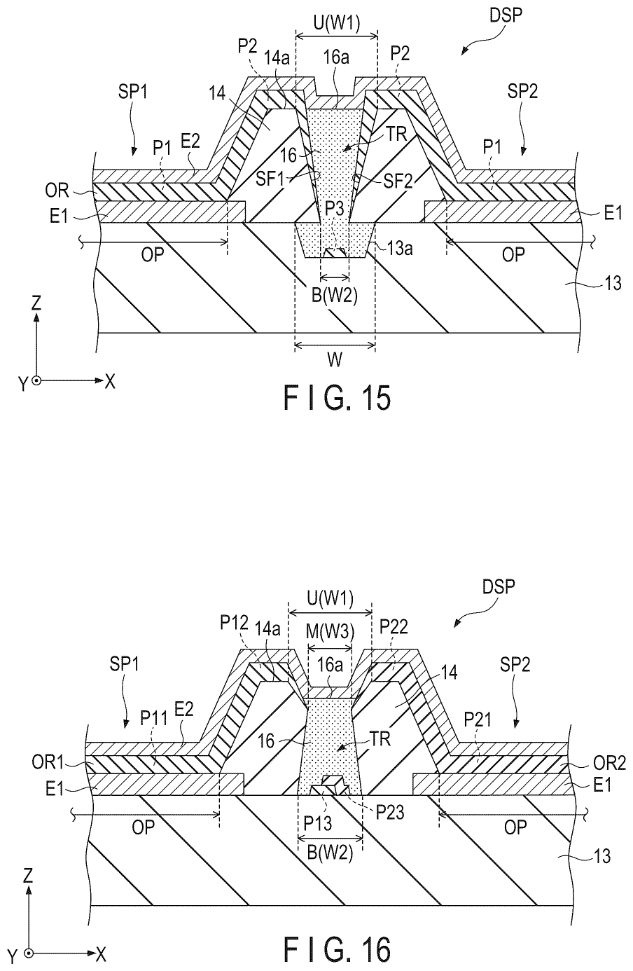

FIG. 15 is a schematic cross-sectional view of a display device DSP according to a ninth embodiment. This figure shows the structure of the boundary between subpixels SP1 and SP2. It should be noted that a similar structure can be applied to the boundary between subpixels SP2 and SP3 and the boundary between subpixels SP1 and SP3.

In the example of FIG. 15, an insulating layer 13 comprises a recess 13a connected to a trench TR. The trench TR has a forward tapered shape. In other words, the first width W1 of the upper portion U of the trench TR is greater than the second width W2 of a lower portion B (W1>W2). The recess 13a has width W greater than the second width W2 (W>W2).

The second portion P2 of an organic layer OR covers at least part of side surfaces SF1 and SF2. The third portion P3 of the organic layer OR is located in the recess 13a and is spaced apart from the second portion P2.

In a manner similar to that of the example of FIG. 5, the upper surface 16a of a filling member 16 is coincident with the upper portion U of the trench TR. It should be noted that the upper surface 16a may have a shape which protrudes from the upper portion U like the protrusion PT shown in FIG. 8. The upper surface 16a may be located between the lower portion B and the upper portion U. The filling member 16 fills the recess 13a. A second electrode E2 continuously covers a first portion P1, the second portion P2 and the upper surface 16a of the filling member 16.

To manufacture this display device DSP, the trench TR is formed in a rib 14 by etching. By this etching, the recess 13a is formed in the insulating layer 13. When the materials of the insulating layer 13 and the rib 14 are selected such that the etching rate of the insulating layer 13 is greater than that of the rib 14, as shown in FIG. 15, the recess 13a having a width greater than that of the lower portion B of the trench TR can be formed by the etching.

When the organic layer OR is formed by vacuum deposition after the formation of the trench TR, the organic layer OR is divided in the lower portion B. Subsequently, the filling member 16 is formed by, for example, the method shown in FIG. 6B and FIG. 6C, and the second electrode E2 is formed on the organic layer OR and the filling member 16. As the trench TR is filled with the filling member 16, the division of the second electrode E2 can be prevented in a manner similar to that of each embodiment described above.

### Tenth Embodiment

Each of the embodiments described above assumes a case where all of the light emitting layers EL included in the organic layers OR of subpixels SP1, SP2 and SP3 emit light exhibiting the same color. The present embodiment assumes a case where the light emitting layers EL included in the organic layers OR of subpixels SP1, SP2 and SP3 emit light exhibiting different colors.

FIG. 16 is a schematic cross-sectional view of a display device DSP according to a tenth embodiment. This figure shows the structure of the boundary between subpixels SP1 and SP2. It should be noted that a similar structure can be applied to the boundary between subpixels SP2 and SP3 and the boundary between subpixels SP1 and SP3. The shapes of the trench TR, filling member 16 and second electrode E2 shown in FIG. 16 are the same as FIG. 11.

In the example of FIG. 16, an organic layer OR1 is provided in subpixel SP1, and an organic layer OR2 is provided in subpixel SP2. The organic layer OR1 comprises, for example, a light emitting layer EL which emits red light. The organic layer OR2 comprises, for example, a light emitting layer EL which emits green light. Although not shown in the section of FIG. 16, the organic layer OR provided in subpixel SP3 comprises a light emitting layer EL which emits blue light.

The organic layer OR1 comprises a first portion P11 which covers the first electrode E1 of subpixel SP1 through an opening OP, a second portion P12 which covers, of a rib 14, the portion on the subpixel SP1 side relative to the trench TR, and a third portion P13 located in the trench TR. The organic layer OR2 comprises a first portion P21 which covers the first electrode E1 of subpixel SP2 through an opening OP, a second portion P22 which covers, of the rib 14, the portion on the subpixel SP2 side relative to the trench TR, and a third portion P23 located in the trench TR. In the example of FIG. 16, the third portion P23 covers part of the third portion P13.

The organic layer OR1 is formed by vacuum deposition using a mask which is open in subpixel SP1. The organic layer OR2 is formed by vacuum deposition using a mask which is open in subpixel SP2 after the formation of the organic layer OR1.

As each of the organic layers OR1 and OR2 is formed into a size having a margin with respect to the shape of the opening OP, the end portions may overlap each other. When the end portions of the organic layers OR1 and OR2 overlap each other, crosstalk could occur in the organic layers OR1 and OR2. In the example of FIG. 16, an end portion of the organic layer OR1, namely, the third portion P13, is spaced apart from the second portion P12. Further, an end portion of the organic layer OR2, namely, the third portion P23, is spaced apart from the second portion P22. By this configuration, even if the third portions P13 and P23 overlap each other, the other portions of the organic layers OR1 and OR2 are separated from each other, thereby preventing crosstalk.

In the example of FIG. 16, the trench TR having a shape similar to that of FIG. 11 is shown. However, even if the trench TR has any shape of the embodiments described above, effects similar to those of the present embodiment can be obtained.

In addition, the following case is assumed. Part of the layers constituting the organic layer OR of each of subpixels SP1, SP2 and SP3 (for example, the light emitting layer EL) is formed using a mask which is different from the other subpixels, and the other common layers (for example, functional layers F1 and F2) are formed for the entire display area DA without using a mask. In this case, similarly, if the common layers are connected to each other in subpixels SP1, SP2 and SP3, crosstalk could occur. When the trench TR in each of the embodiments described above is provided in the rib 14, the common layers are divided in the boundaries of subpixels SP1, SP2 and SP3. Thus, the crosstalk described above can be prevented.

### Eleventh Embodiment

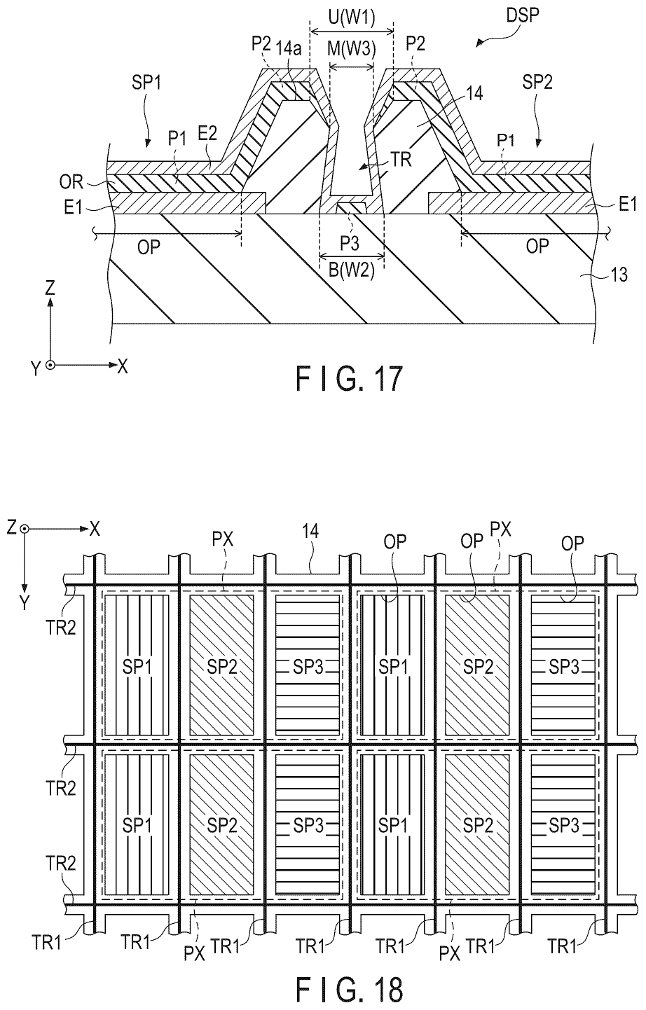

FIG. 17 is a schematic cross-sectional view of a display device DSP according to an eleventh embodiment. This figure shows the structure of the boundary between subpixels SP1 and SP2. It should be noted that a similar structure can be applied to the boundary between subpixels SP2 and SP3 and the boundary between subpixels SP1 and SP3. The shapes of the trench TR and organic layer OR shown in FIG. 17 are the same as FIG. 11.

In the example of FIG. 17, a filling member 16 is not provided in the trench TR. A second electrode E2 covers the first and second portions P1 and P2 of the organic layer OR and also continuously covers the inner surface of the trench TR. Inside the trench TR, the second electrode E2 covers the third portion P3 of the organic layer OR.

The second electrode E2 is formed of, for example, a metal material, and is formed by a chemical vapor deposition (CVD) method, in which the property of film formation for a wall portion such as the inner surface of the trench TR is high, etc. When the trench TR has a forward tapered shape between a middle portion M and an upper portion U as shown in FIG. 17, the second electrode E2 which covers the inner surface of the trench TR is easily formed compared with a case where the entire trench TR has an inverse tapered shape. However, if the second electrode E2 which covers the inner surface of the trench TR can be formed, the other shapes disclosed in the embodiments described above could be applied to the trench TR.

In the present embodiment, as there is no need to provide the filling member 16, the manufacturing process of the display device DSP can be simplified compared with the other embodiments.

### Twelfth Embodiment

FIG. 18 is a plan view showing examples of subpixels SP1, SP2 and SP3, a rib 14 and trenches TR according to a twelfth embodiment. The layout of subpixels SP1, SP2 and SP3 and the shape of the rib 14 are the same as the example of FIG. 2.

In the example of FIG. 18, the rib 14 comprises a plurality of first trenches TR1 and a plurality of second trenches TR2. The first trenches TR1 are located between subpixels SP1 and SP2 which are adjacent to each other in a first direction X, between subpixels SP2 and SP3 which are adjacent to each other in the first direction X and between subpixels SP1 and SP3 which are adjacent to each other in the first direction X, and all of the first trenches TR1 extend in a second direction Y. In other words, each first trench TR1 is located in the boundary between subpixels SP exhibiting different colors.

Each second trench TR2 is located between two subpixels SP1 which are adjacent to each other in the second direction Y, between two subpixels SP2 which are adjacent to each other in the second direction Y and between two subpixels SP3 which are adjacent to each other in the second direction Y, and extends in the first direction X. In other words, each second trench TR2 is located in the boundary between subpixels SP exhibiting the same color.

When the trenches TR1 and TR2 are provided in line with a grating shape in this manner, crosstalk can be prevented in subpixels SP which are adjacent to each other in the second direction Y in addition to subpixels SP which are adjacent to each other in the first direction X.

The configurations disclosed in the first to twelfth embodiments can be appropriately combined with each other. For example, in the shape of the trench TR shown in FIG. 5, the filling member 16 may comprise the protrusion PT as shown in FIG. 8, and the protective member RF may be provided in the edge portion of the opening OP as shown in FIG. 9, and further, the second electrode E2 may consist of a plurality of layers as shown in FIG. 10. Alternatively, in the shapes of the trenches TR shown in FIG. 11 and FIG. 13 to FIG. 16, the filling member 16 may comprise the protrusion PT as shown in FIG. 8, and the protective member RF may be provided in the edge portion of the opening OP as shown in FIG. 9, and further, the second electrode E2 may consist of a plurality of layers as shown in FIG. 10.

All of the display devices that can be implemented by a person of ordinary skill in the art through arbitrary design changes to the display device described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate;
an insulating layer provided on the substrate;
a first electrode provided on the insulating layer;
a rib provided on the insulating layer, and comprising an opening which overlaps the first electrode, and a trench which does not overlap the first electrode;
an organic layer which includes a light emitting layer and covers the first electrode and the rib;
a filling member provided in the trench; and
a second electrode which covers the organic layer, the rib and the filling member, wherein
the organic layer includes:
a first portion which covers the first electrode;
a second portion which covers, of the rib, a portion located between the opening and the trench; and
a third portion located in the trench and spaced apart from the second portion.

2. The display device of claim 1, wherein
the filling member covers the third portion.

3. The display device of claim 1, further comprising a protective member provided between the organic layer and the second electrode in an end portion of the opening, wherein
the protective member and the filling member are formed of a same material.

4. The display device of claim 1, wherein
the second electrode includes:
a first layer which covers the organic layer; and
a second layer which covers the first layer,
part of the first layer is located in the trench and is covered with the filling member, and
the second layer covers the filling member.

5. The display device of claim 1, wherein
the trench comprises:
an upper portion having a first width; and
a lower portion having a second width greater than the first width.

6. The display device of claim 1, wherein
the trench comprises:
an upper portion having a first width;
a lower portion having a second width; and
a middle portion located between the upper portion and the lower portion, and having a third width less than the first width and the second width.

7. The display device of claim 6, wherein
an upper surface of the filling member is located between the upper portion and the middle portion.

8. The display device of claim 1, further comprising first and second metal layers located between the insulating layer and the rib, wherein
the rib comprises first and second side surfaces of the trench,
the insulating layer comprises a recess connected to the trench,
the first metal layer protrudes from the first side surface and blocks part of the recess,
the second metal layer protrudes from the second side surface and blocks part of the recess, and
the first metal layer and the second metal layer face each other across an intervening gap in the trench.

9. The display device of claim 1, wherein
the trench comprises:
an upper portion having a first width; and
a lower portion having a second width less than the first width, and
the insulating layer comprises a recess having a width greater than the second width and connected to the trench.

10. The display device of claim 1, further comprising a plurality of subpixels which are arranged in a first direction and a second direction intersecting with the first direction and each of which includes the first electrode, and
the trench is provided at least between the subpixels which are adjacent to each other in the first direction.

11. The display device of claim 10, wherein
the trench is provided further between the subpixels which are adjacent to each other in the second direction.

12. The display device of claim 1, wherein
a void is formed between the filling member and the insulating layer in the trench.

13. The display device of claim 12, wherein
the third portion is located in the void.

14. The display device of claim 1, wherein
the filling member comprises a protrusion which overflows from the trench.

15. The display device of claim 14, wherein
the protrusion protrudes to an upper side relative to the second portion.

16. The display device of claim 6, wherein
part of the organic layer covers a side surface of the trench located between the upper portion and the middle portion.

17. The display device of claim 1, wherein
the organic layer includes first and second organic layers which emit light exhibiting different colors, and
the third portion includes part of the first organic layer and part of the second organic layer.

18. The display device of claim 17, wherein
the part of the second organic layer covers the part of the first organic layer.

19. A display device comprising:
a substrate;
an insulating layer provided on the substrate;
a first electrode provided on the insulating layer;
a rib provided on the insulating layer, and comprising an opening which overlaps the first electrode, and a trench which does not overlap the first electrode;
an organic layer which includes a light emitting layer and covers the first electrode and the rib; and
a second electrode which continuously covers the organic layer and an inner surface of the trench, wherein
the organic layer includes:
a first portion which covers the first electrode;
a second portion which covers, of the rib, a portion located between the opening and the trench; and
a third portion located in the trench and spaced apart from the second portion.

20. The display device of claim 19, wherein
the trench comprises:
an upper portion having a first width;
a lower portion having a second width; and
a middle portion located between the upper portion and the lower portion and having a third width less than the first width and the second width.
